(19) United States
(12) Patent Application Publication
(10) Pub. No.: US 2025/0183230 A1
(43) Pub. Date: Jun. 5, 2025

(54) CHIP STACK PACKAGE AND METHOD OF MANUFACTURING THE SAME

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/914,443

(22) Filed: Oct. 14, 2024

(30) Foreign Application Priority Data
Dec. 4, 2023 (KR) 10-2023-0173525

(51) Int. Cl. H01L 25/065; H01L 23/00; H01L 25/00

(52) U.S. Cl. CPC H01L 25/0657; H01L 24/05; H01L 24/08; H01L 24/09; H01L 24/27; H01L 24/32; H01L 24/95; H01L 25/50; H01L 24/80; H01L 2224/0556; H01L 2224/08145; H01L 2224/09181; H01L 2224/2746; H01L 2224/2747; H01L 2224/32057; H01L 2224/32145; H01L 2224/32221; H01L 2224/80896; H01L 2224/95; H01L 2225/06565

(57) ABSTRACT

A chip stack package and a method of manufacturing the same are described. Semiconductor chips each including a semiconductor substrate, a first dielectric layer, and a connecting pattern are stacked. The connecting pattern is formed positioned within the first dielectric layer and has a first side surface along a side surface of the stacked semiconductor chips. Conductive pillars are formed connected to a plurality of the first side surfaces of the connecting patterns of the stacked semiconductor chips, connecting the stacked semiconductor chips to each other. The semiconductor substrates are recessed from the second side surfaces of the first dielectric layer. A second dielectric layer is formed to cover the conductive pillars and to fill spaces between the recessed semiconductor substrates and the conductive pillars.

### CROSS-REFERENCE TO RELATED APPLICATIONS

The present application claims priority under 35 U.S.C. § 119 (a) to Korean Patent Application No. 10-2023-0173525, filed on Dec. 4, 2023, which application is incorporated herein by reference in its entirety.

### BACKGROUND

### 1. Technical Field

The present disclosure generally relates to packaging technology, including but not limited to a chip stack package and a method of manufacturing the same.

### 2. Related Art

Electronic devices require high-performance and large-capacity semiconductor packages. The semiconductor package is configured to include a plurality of semiconductor chips and is a smaller size is advantageous. A chip stack package in which a plurality of semiconductor chips are three-dimensionally stacked has been developed.

### SUMMARY

The present disclosure provides a method of manufacturing a chip stack package, the method may include stacking semiconductor chips, each of the semiconductor chips including a semiconductor substrate, a first dielectric layer positioned over the semiconductor substrate, and a connecting pattern positioned within the first dielectric layer, wherein the connecting pattern has a first side surface, the first dielectric layer has a second side surface, and the second side surface and the first side surface are exposed, forming conductive pillars connected to a plurality of the first side surfaces of the connecting patterns of the stacked semiconductor chips, connecting the stacked semiconductor chips to each other, recessing the semiconductor substrates from the second side surfaces, and forming a second dielectric layer covering the conductive pillars and filling spaces between the recessed semiconductor substrates and the conductive pillars.

The present disclosure provides a method of manufacturing a chip stack package, the method may include forming semiconductor chips, each of the semiconductor chips including a semiconductor substrate, a first dielectric layer positioned over the semiconductor substrate, and a connecting pattern within the first dielectric layer, wherein the connecting pattern has a first side surface, the first dielectric layer has a second side surface, and the second side surface and the first side surface are exposed, arranging a first stack of semiconductor chips spaced apart from a second stack of the semiconductor chips over a base, forming conductive pillars connecting a plurality of the first side surfaces of the connecting patterns of the stacked semiconductor chips, wherein a first section of the conductive pillars is connected to the first stack and a second section of the conductive pillars is connected to the second stack, recessing edges of the semiconductor substrates included in the first stack and the second stack from the second side surfaces, forming a second dielectric layer covering the first stack and the second stack, and removing portions of the second dielectric layer by exposing and developing the portions to separate the first stack from the second stack.

The present disclosure provides a chip stack package that may include a stack comprising stacked semiconductor chips, each of the semiconductor chips including a semiconductor substrate, a first dielectric layer positioned over the semiconductor substrate, and a connecting pattern within the first dielectric layer, wherein the connecting pattern has a first side surface, the first dielectric layer has a second side surface, and the second side surface is adjacent to the first side surface, conductive pillars connected to a plurality of the first side surfaces of the connecting patterns of the stacked semiconductor chips, connecting the stacked semiconductor chips to each other, and a second dielectric layer covering the conductive pillars. The semiconductor substrates are recessed from the second side surfaces, and the second dielectric layer fills spaces between the recessed semiconductor substrates and the conductive pillars.

### BRIEF DESCRIPTION OF THE DRAWINGS

FIG. 1 and FIG. 2 are schematic views illustrating connecting patterns formed utilizing a method of manufacturing a chip stack package according to an embodiment of the present disclosure.

FIG. 3 and FIG. 4 are schematic views illustrating directions for dicing semiconductor chips from a parent substrate as utilized during a method of manufacturing of a chip stack package according to an embodiment of the present disclosure.

FIG. 5 and FIG. 6 are schematic views illustrating semiconductor chips arranged over a base during a method of manufacturing a chip stack package according to an embodiment of the present disclosure.

FIG. 7 and FIG. 8 are schematic views illustrating stacked semiconductor chips according to a method of manufacturing a chip stack package according to an embodiment of the present disclosure.

FIG. 9 and FIG. 10 are schematic views illustrating a plating seed layer formed utilizing a method of manufacturing a chip stack package according to an embodiment of the present disclosure.

FIG. 11 is a schematic view illustrating a resist layer formed during a method of manufacturing a chip stack package according to an embodiment of the present disclosure.

FIG. 12 and FIG. 13 are schematic views illustrating openings formed in a resist layer during a method of manufacturing a chip stack package according to an embodiment of the present disclosure.

FIG. 14 and FIG. 15 are schematic views illustrating conductive pillars formed according to a method of manufacturing a chip stack package according to an embodiment of the present disclosure.

FIG. 16 to FIG. 18 are schematic views illustrating a separated plating seed layer in accordance with a method of manufacturing a chip stack package according to an embodiment of the present disclosure.

FIG. 19 to FIG. 21 are schematic views illustrating recessed semiconductor substrates during a method of manufacturing of a chip stack package according to an embodiment of the present disclosure.

FIG. 22 and FIG. 23 are schematic views illustrating a dielectric layer formed during a method of manufacturing a chip stack package according to an embodiment of the present disclosure.

FIG. 24 to FIG. 27 are schematic views illustrating portions of the dielectric layer to be removed during a method of manufacturing a chip stack package according to an embodiment of the present disclosure.

FIG. 28 and FIG. 29 are schematic views illustrating a chip stack package according to an embodiment of the present disclosure.

FIG. 30 and FIG. 31 are schematic views illustrating guard ring structures formed during a method of manufacturing a chip stack package according to an embodiment of the present disclosure.

### DETAILED DESCRIPTION

Terms such as “first” and “second” are used to distinguish between various elements and do not imply size, order, priority, or importance of the elements and do not limit the elements. Terms such as “top,” “bottom,” “side,” “under,” “over,” “on,” “laterally,” and other terms implying relative spatial relationship or orientation are utilized only for the purpose of ease of description or reference to a drawing and are not otherwise limiting. When one element is identified as “connected” to another element, the elements may be connected directly or through an intervening element between the elements. When two elements are identified as “directly connected,” one element is directly connected or coupled to the other element without an intervening element between the two elements. When an element is identified as “on,” “over,” or “under” another element, these elements may directly contact each other or an intervening element may be disposed between these elements.

The cross-hatching throughout the figures illustrates corresponding or similar areas between the figures rather than indicating the materials for the areas. Figures are not necessarily drawn to scale.

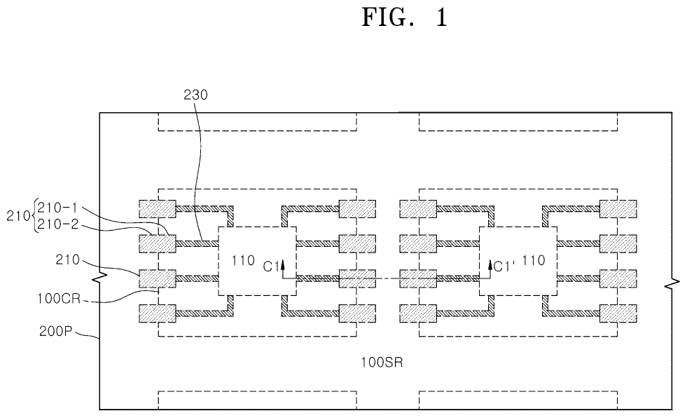

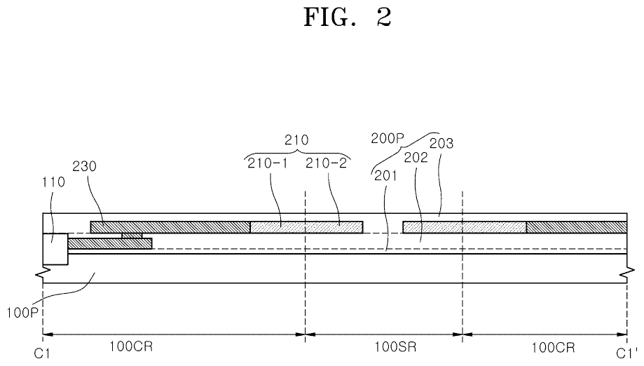

FIG. 1 and FIG. 2 are schematic views illustrating connecting patterns 210 formed utilizing a method of manufacturing a chip stack package according to an embodiment of the present disclosure. FIG. 1 is a plan view illustrating the arrangement of the connecting patterns 210, and FIG. 2 is a cross-sectional view illustrating a cross-section taken along the cutting line C1-C1′ of FIG. 1.

Referring to FIG. 1 and FIG. 2, integrated circuits 110 are formed over a parent substrate 100P. The parent substrate 100P may include a semiconductor material such as silicon (Si). The parent substrate 100P may be a semiconductor wafer. The parent substrate 100P includes the arrangement of a plurality of chip regions 100CR. A scribe lane region 100SR is positioned or located between consecutive chip regions 100CR. The scribe lane region 100SR may be a cross-shaped region. The scribe lane region 100SR may each of the chip regions 100CR in a square shape or a rectangular shape.

The integrated circuits 110 are formed in the chip regions 100CR of the parent substrate 100P. The scribe lane region 100SR is a region within which the integrated circuits 110 are not disposed or a region within which interconnections are not disposed. The integrated circuits 110 may be formed to configure semiconductor devices such as DRAM devices or NAND flash devices. A parent dielectric layer 200P is formed over the parent substrate 100P. The parent dielectric layer 200P may include a dielectric material such as silicon oxide. The parent dielectric layer 200P may be formed to insulate the integrated circuits 110 formed over the parent substrate 100P.

Interconnections or conductive patterns 230 are formed within the parent dielectric layer 200P. The conductive patterns 230 are formed to electrically connect to the integrated circuits 110. The conductive patterns 230 may be formed in a metallization structure. The connecting patterns 210 are formed within the parent dielectric layer 200P. The connecting patterns 210 may be connected to the conductive patterns 230. The connecting patterns 210 are electrically connected to the integrated circuits 110 through the conductive patterns 230. The connecting patterns 210 are connectors or bonding pads that electrically connect the integrated circuits 110 to an external device. Each of the conductive pattern 230 and the connecting pattern 210 may include a metallic layer including aluminum (Al) or copper (Cu).

The parent dielectric layer 200P is formed to insulate the conductive patterns 230 and the connecting patterns 210. The parent dielectric layer 200P is formed in a multilayer structure including a first sub-dielectric layer 201, a second sub-dielectric layer 202, and a third sub-dielectric layer 203. The first sub-dielectric layer 201 is formed to cover the parent substrate 100P, the second sub-dielectric layer 202 is formed on the first sub-dielectric layer 201, and the third sub-dielectric layer 203 is formed on the second sub-dielectric layer 202. The conductive patterns 230 are positioned within the second sub-dielectric layer 202 and the third sub-dielectric layer 203. The connecting patterns 210 are formed within the third sub-dielectric layer 203. The third sub-dielectric layer 203 fills the spaces between the connecting patterns 210 to electrically isolate different sections of the connecting patterns 210.

The connecting patterns 210 are formed to extend across both the chip region 100CR and the scribe lane region 100SR of the parent substrate 100P. The connecting patterns 210 are formed to extend outside the boundaries of the chip regions 100CR. Each of the connecting patterns 210 includes a first portion 210-1 and a second portion 210-2. The first portions 210-1 of the connecting patterns 210 are positioned within the chip regions 100CR where the integrated circuits 110 are disposed. The second portions 210-2 of the connecting patterns 210 extend from the first portions 210-1 and are positioned within the scribe lane region 100SR. The connecting patterns 210 are advantageously formed as a single element. The conductive patterns 230 are connected to the first portions 210-1 of the connecting patterns 210. The connecting patterns 210 are connected to the integrated circuits 110 through the conductive patterns 230.

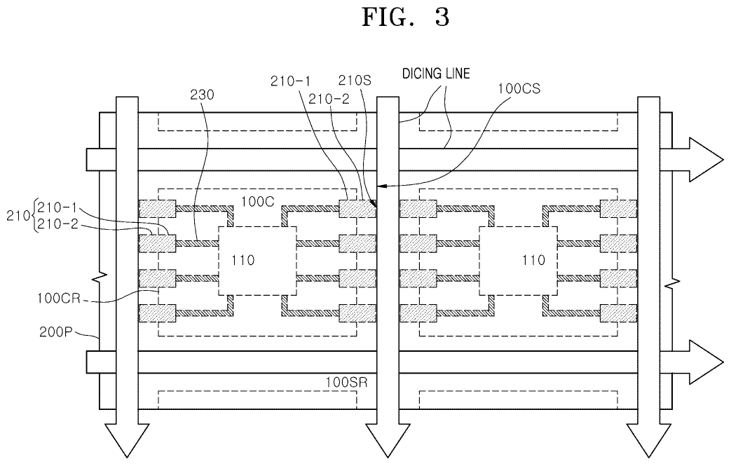

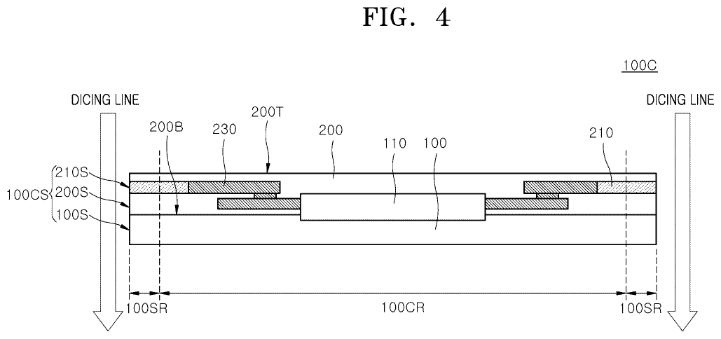

FIG. 3 and FIG. 4 are schematic views illustrating directions for dicing the semiconductor chips 100C from the parent substrate 100P as utilized during the method of manufacturing the chip stack package according to an embodiment of the present disclosure. FIG. 3 is a plan view illustrating the directions in which the parent substrate 100P is diced, and FIG. 4 is a cross-sectional view illustrating a semiconductor chip 100C separated from the parent substrate 100P.

Referring to FIG. 3 and FIG. 4, the structure including the parent substrate 100P and the parent dielectric layer 200P is diced to separate the semiconductor chips 100C from the structure including the parent substrate 100P and the parent dielectric layer 200P. Portions of the parent substrate 100P and parent dielectric layer 200P are removed to form the semiconductor chips 100C including the chip regions 100CR. Various dicing devices may be used during the process of dicing the structure including the parent substrate 100P and the parent dielectric layer 200P. The parent substrate 100P and the parent dielectric layer 200P may be diced using a sawing blade. The process of dicing the parent substrate 100P and the parent dielectric layer 200P is performed, for example, along dicing lines extending through the scribe lane region 100SR. The dicing lines are illustrated by wide arrows in FIG. 3 and FIG. 4.

As the structure including the parent substrate 100P and the parent dielectric layer 200P is diced into the semiconductor chips 100C, each of the semiconductor chips 100C includes a semiconductor substrate 100, a first dielectric layer 200, the conductive patterns 230, and the connecting patterns 210. Because the semiconductor substrate 100 is separated from the parent substrate 100P, the parent substrate 100P is an element that provides the diced semiconductor substrate 100. Because the first dielectric layer 200 is separated from the parent dielectric layer 200P, the parent dielectric layer 200P is an element that provides the diced first dielectric layer 200.

The parent substrate 100P and the parent dielectric layer 200P are diced such that first side surfaces 210S of the second portions 210-2 of the connecting patterns 210 are exposed. The dicing process is performed such that the dicing lines on which the dicing process is performed pass through portions of the second portions 210-2 of the connecting patterns 210. Accordingly, as the parent substrate 100P and the parent dielectric layer 200P are diced, portions of the second portions 210-2 of the connecting patterns 210 are diced and removed.

As illustrated in FIG. 4, in the diced semiconductor chip 100C, the first side surfaces 210S of the connecting patterns 210 are adjacent to and aligned with the diced side surface 200S of the first dielectric layer 200. The first dielectric layer 200 has a first (bottom) surface 200B facing the semiconductor substrate 100 and a second (top) surface 200T opposite to the first surface 200B. The side surface 200S of the first dielectric layer 200 is a side surface between the first surface 200B and the second surface 200T. A side surface 100CS of the semiconductor chip 100C includes the diced side surface 200S of the first dielectric layer 200, a diced side surface 100S of the semiconductor substrate 100, and the side surface 210S of the connecting pattern 210. The diced side surface 200S of the first dielectric layer 200, the diced side surface 100S of the semiconductor substrate 100, and the side surface 210S of the connecting pattern 210 may all be aligned and/or disposed along the side surface of the stacked semiconductor chips. The first side surface 210S of the connecting pattern 210, the side surface 200S of the first dielectric layer 200, and the diced side surface 100S of the semiconductor substrate 100 are side surfaces that are adjacent to each other as shown in FIG. 4.

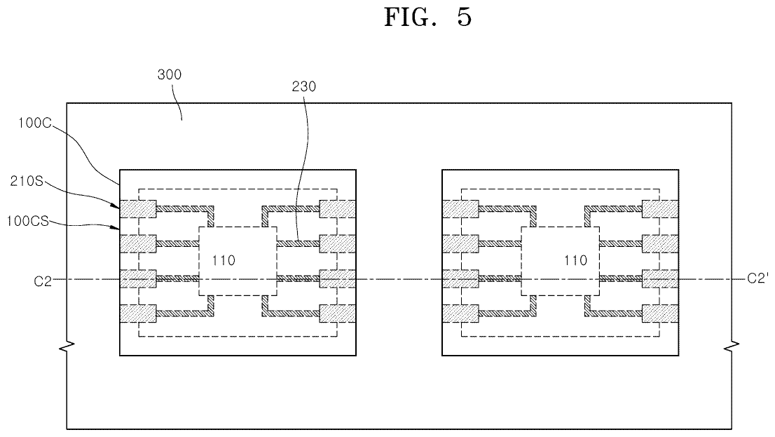

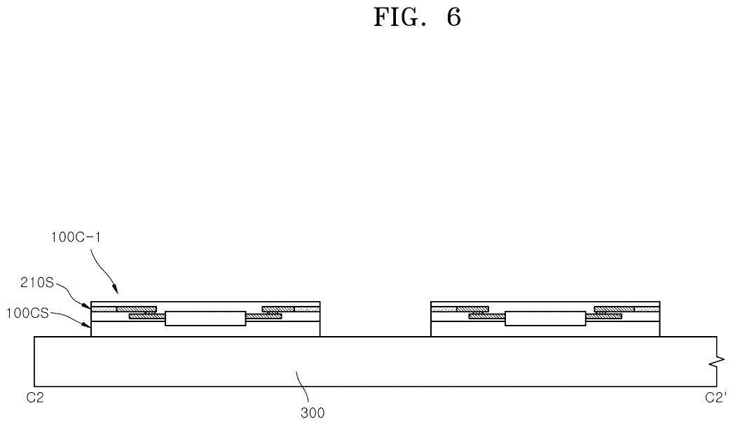

FIG. 5 and FIG. 6 are schematic views illustrating first semiconductor chips 100C-1 arranged over a base 300 during the method of manufacturing the chip stack package according to an embodiment of the present disclosure. FIG. 6 is a view illustrating a cross-section taken along the cutting line C2-C2′ of the plan view of FIG. 5.

Referring to FIG. 5 and FIG. 6, the first semiconductor chips 100C-1, which are some of the diced semiconductor chips 100C, are arranged over the base 300. The first semiconductor chips 100C-1 are arranged over the base 300 and laterally spaced apart from each other. The first semiconductor chips 100C-1 are arranged over the base 300 such that the side surfaces 100CS of adjacent semiconductor chips 100C-1 face each other, thus the first side surfaces 210S of the connecting patterns 210 face each other. An adhesive layer (not shown) may be interposed between the base 300 and the first semiconductor chips 100C-1 to attach the first semiconductor chips 100C-1 to the base 300. The base 300 may be a supporter or a handling wafer that supports the diced semiconductor chips 100C such that subsequent processes may be performed on the diced semiconductor chips 100C. The base 300 may be a glass substrate, a semiconductor substrate, or a metallic substrate.

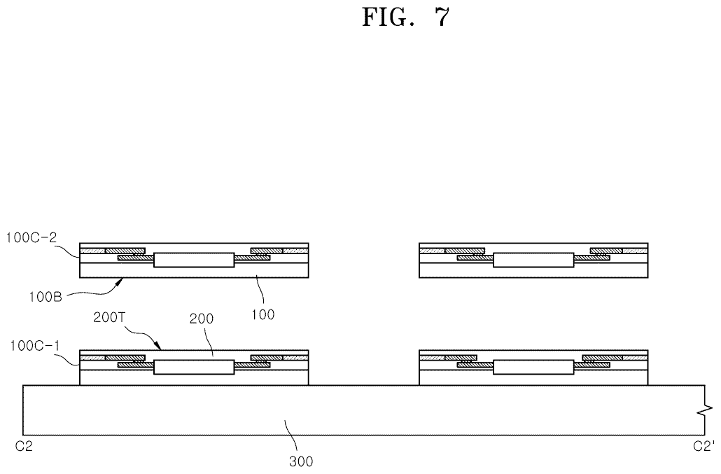

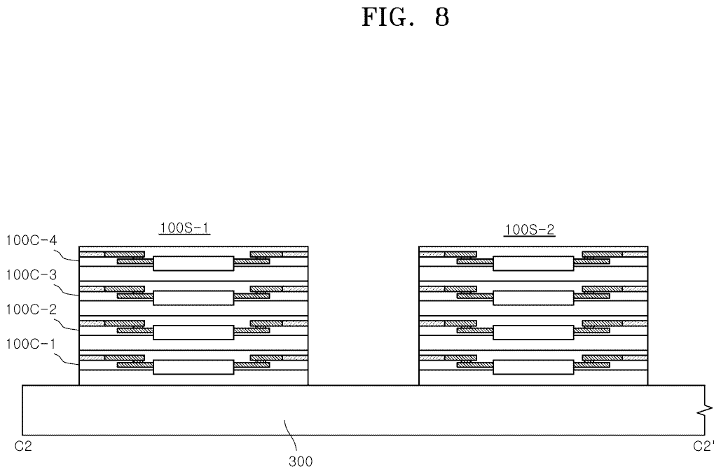

FIG. 7 is a schematic view illustrating a second semiconductor chip 100C-2 stacked on the first semiconductor chip 100C-1 according to the method of manufacturing the chip stack package according to an embodiment of the present disclosure. FIG. 8 is a schematic view illustrating stacks 100S-1 and 100S-2 in which the semiconductor chips 100C are stacked in accordance with the method of manufacturing the chip stack package according to an embodiment of the present disclosure.

Referring to FIG. 7, a second semiconductor chip 100C-2 is stacked on the first semiconductor chip 100C-1. The second semiconductor chip 100C-2 may be stacked on the first semiconductor chip 100C-1 using a chip-to-chip bonding method. The second semiconductor chip 100C-2 is one of the diced semiconductor chips 100C. The bottom surface 100B of the second semiconductor chip 100C-2 is directly bonded to the top surface 200T of the first semiconductor chip 100C-1 without an adhesive material. The bottom surface 100B of the semiconductor substrate 100 of the second semiconductor chip 100C-2 may be directly bonded to the top surface 200T of the first dielectric layer 200 of the first semiconductor chip 100C-1. The top or second surface 200T of the first dielectric layer 200T of the first semiconductor chip 100C-1 is a top surface of the first semiconductor chip 100C-1, and the bottom or third surface 100B of the semiconductor substrate 100 of the second semiconductor chip 100C-2 is a bottom surface of the second semiconductor chip 100C-2. The top surface 200T of the first dielectric layer 200 of the first semiconductor chip 100C-1 and the bottom surface 100B of the semiconductor substrate 100 of the second semiconductor chip 100C-2 may be bonded to each other by covalent bonds. For example, the top surface 200T of the first dielectric layer 200 of the first semiconductor chip 100C-1 and the bottom surface 100B of the semiconductor substrate 100 of the second semiconductor chip 100C-2 may be directly bonded to each other by covalent bonds between silicon (Si)-dielectric material or covalent bonds between silicon (Si)-oxygen (O). To induce such direct bonding, a process of activating the top surface 200T of the first dielectric layer 200T of the first semiconductor chip 100C-1 and the bottom surface 100B of the semiconductor substrate 100 of the second semiconductor chip 100C-2 may be performed. For example, a surface treatment process with hydrogen plasma may be performed as the process of activating the surfaces. After performing the surface treatment process, heat treatment may be performed in a state in which the bottom surface 100B of the semiconductor substrate 100 of the second semiconductor chip 100C-2 is bonded to the top surface 200T of the first dielectric layer 200 of the first semiconductor chip 100C-1, thereby inducing covalent bonding between the surfaces 200T and 100B.

The second semiconductor chip 100C-2 is stacked on the first semiconductor chip 100C-1, a third semiconductor chip 100C-3 is stacked on the second semiconductor chip 100C-2, and a fourth semiconductor chip 100C-4 is stacked on the third semiconductor chip 100C-3, such as shown in FIG. 8. As illustrated in FIG. 8, the first stack 100S-1 of the semiconductor chips 100C including the semiconductor chips 100C-1, 100C-2, 100C-3, and 100C-4 is formed. The second stack 100S-2 in which the semiconductor chips 100C are stacked may be similarly formed at a position or location spaced apart from the first stack 100S-1. By utilizing direct bonding to stack the semiconductor chips 100C, undesirable increase in the overall height of each of the first stack 100S-1 and the second stack 100S-2 may be prevented compared to the use of adhesive layers between semiconductor chips 100C. When the semiconductor package has a limited height or limited thickness, the quantity of semiconductor chips 100C stacked using direct bonding may be greater than the quantity of semiconductor chips 100C stacked using adhesives.

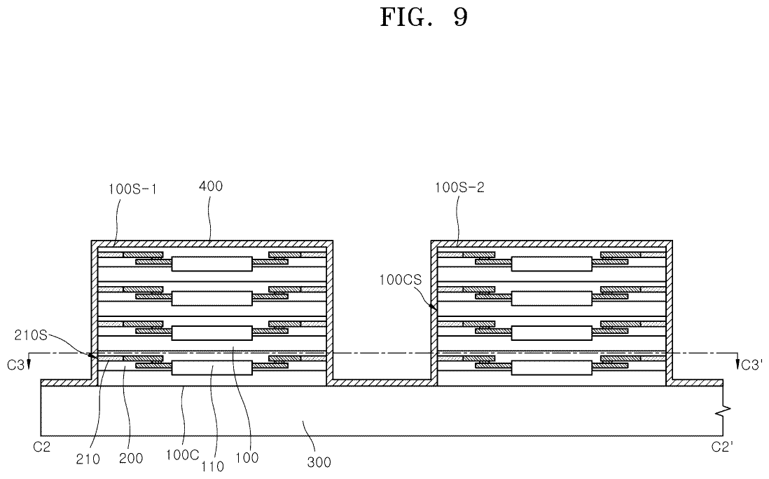

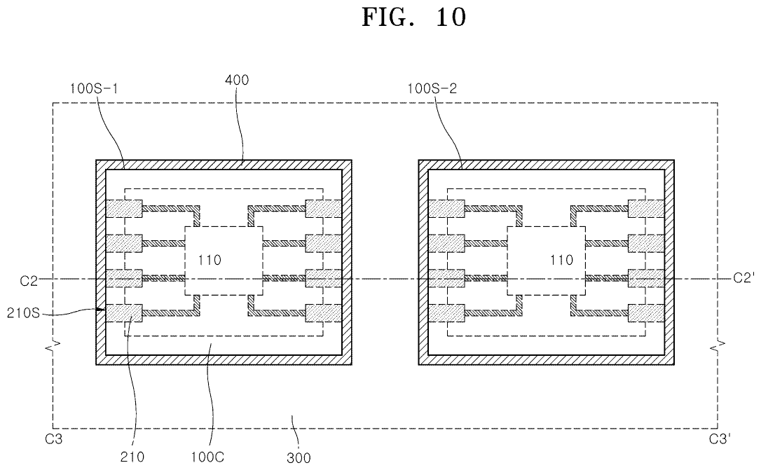

FIG. 9 and FIG. 10 are schematic views illustrating a plating seed layer 400 formed utilizing the method of manufacturing the chip stack package according to an embodiment of the present disclosure. FIG. 9 illustrates a cross-section taken along the cutting line C2-C2′ of FIG. 10, and FIG. 10 illustrates a cross-section taken along the cutting line C3-C3′ of FIG. 9.

Referring to FIG. 9 and FIG. 10, the plating seed layer 400 is formed to cover the first stack 100S-1 and the second stack 100S-2 in which the semiconductor chips 100C are stacked. The plating seed layer 400 covers the first stack 100S-1 and the second stack 100S-2 and extends between onto the base 300 between and around the first stack 100S-1 and the second stack 100S-2. The plating seed layer 400 extends to cover the side surfaces 100CS of the stacked semiconductor chips 100C. The plating seed layer 400 extends to contact or connect the side surfaces 210S of the connecting patterns 210 included in the stacked semiconductor chips 100C. The plating seed layer 400 may include a copper (Cu) layer. The plating seed layer 400 may further include a barrier metal layer that suppresses diffusion of copper (Cu) under the copper (Cu) layer.

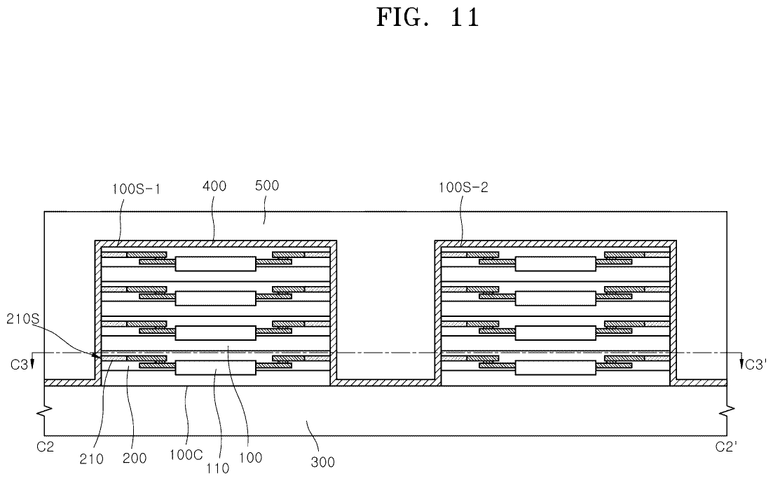

FIG. 11 is a schematic view illustrating a resist layer 500 formed during the method of manufacturing the chip stack package according to an embodiment of the present disclosure. FIG. 11 illustrates a cross-section taken along the cutting line C2-C2′ of FIG. 10.

Referring to FIG. 11, the resist layer 500 covering the stacked semiconductor chips 100C is formed on the plating seed layer 400. The resist layer 500 is formed over the first stack 100S-1 and the second stack 100S-2. The resist layer 500 is formed to fill the space between the first stack 100S-1 and the second stack 100S-2. The resist layer 500 may include a photoresist material.

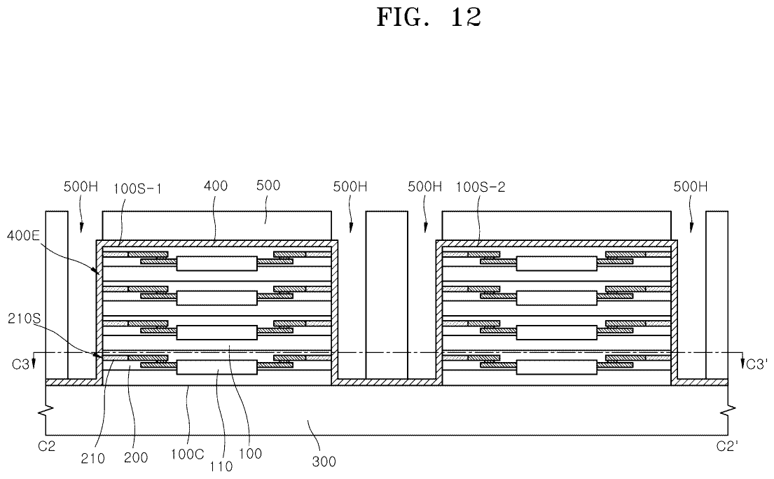

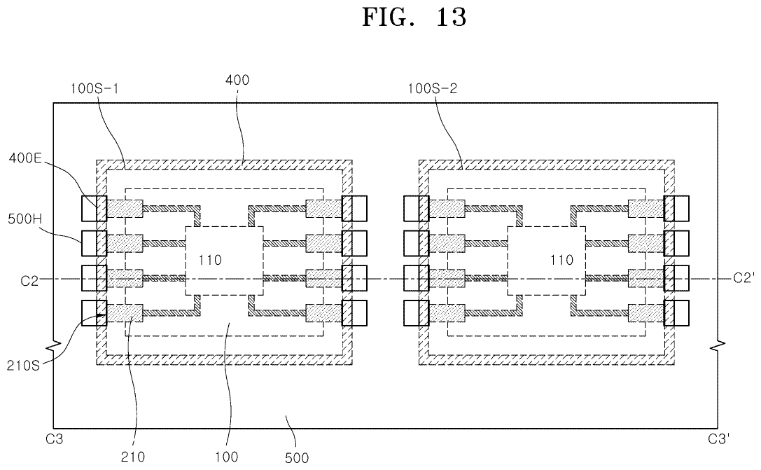

FIG. 12 and FIG. 13 are schematic views illustrating openings 500H formed in the resist layer 500 in the method of manufacturing the chip stack package according to an embodiment of the present disclosure. FIG. 12 illustrates a cross-section taken along the cutting line C2-C2′ of FIG. 13, and FIG. 13 illustrates a cross-section taken along the cutting line C3-C3′ of FIG. 12.

Referring to FIG. 12 and FIG. 13, the openings 500H are formed to penetrate the resist layer 500. The openings 500H may penetrate (not shown) the plating seed layer 400 to expose portions of the plating seed layer 400 at the bottom of the openings 500H. The openings 500H are formed along the edges of the plating seed layer 400 along the first stack 100S-1 and the second stack 100S-2 of the semiconductor chips 100C. The openings 500H are formed adjacent to the plating seed layer 400 that is adjacent to at least a part of the connecting patterns 210 of the semiconductor chips 100C. The openings 500H are formed adjacent to the plating seed layer 400 along the side surfaces 210S of the connecting patterns 210 of the semiconductor chips 100C. The openings 500H are formed to expose portions 400E of the plating seed layer 400 covering the side surfaces of the first stack 100S-1 and the second stack 100S-2 of the semiconductor chips 100C. When the plating seed layer 400 is not utilized, the openings 500H are formed to expose the side surfaces 210S of the connecting patterns 210.

A photolithography process may be performed on the resist layer 500 to form the openings 500H. The openings 500H may be formed by selectively exposing regions of the resist layer 500 and performing a development process to selectively remove the exposed regions.

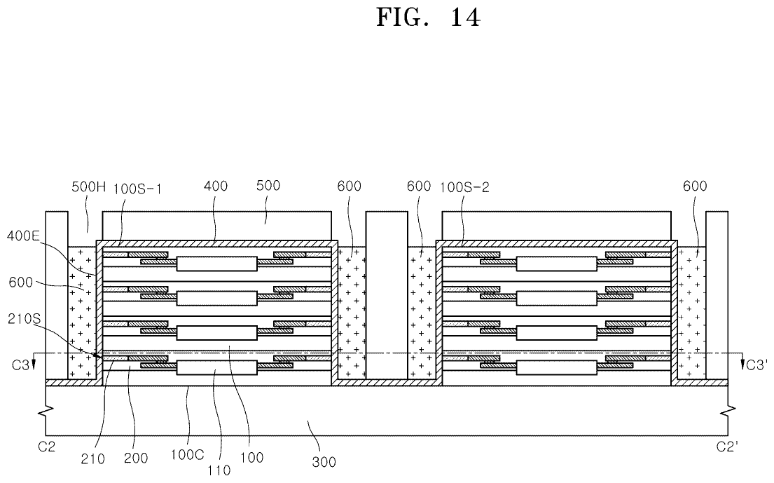

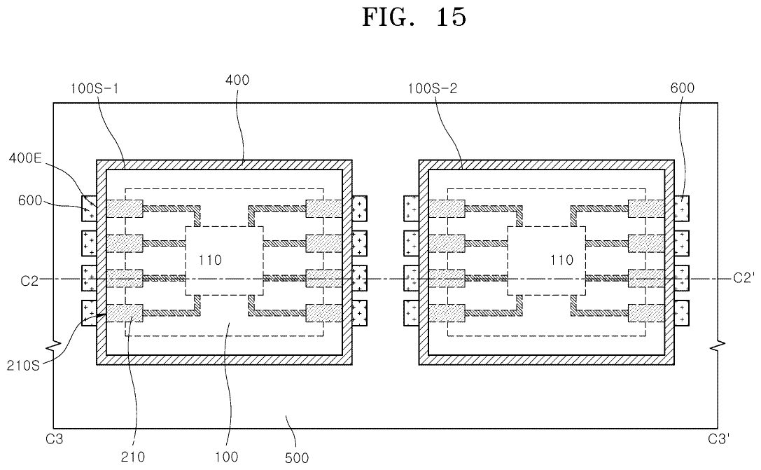

FIG. 14 and FIG. 15 are schematic views illustrating conductive pillars 600 formed according to the method of manufacturing the chip stack package according to an embodiment of the present disclosure. FIG. 14 illustrates a cross-section taken along the cutting line C2-C2′ of FIG. 15, and FIG. 15 illustrates a cross-section taken along the cutting line C3-C3′ of FIG. 14.

Referring to FIG. 14 and FIG. 15, the conductive pillars 600 are formed to connect the semiconductor chips 100C stacked in the first stack 100S-1 to each other. Additional conductive pillars 600 are formed to connect the semiconductor chips 100C stacked in the second stack 100S-2 to each other. The conductive pillars 600 are formed to contact or electrically connect to the side surfaces 210S of the connecting patterns 210 of the semiconductor chips 100C that are substantially vertically stacked. The conductive pillars 600 are formed to contact or electrically connect portions 400E of the plating seed layer 400 exposed by the openings 500H. The conductive pillars 600 are electrically connected to the connecting patterns 210 of the vertically stacked semiconductor chips 100C through the portions 400E of the plating seed layer 400 exposed by the openings 500H.

The openings 500H are filled with a conductive material to form the conductive pillars 600. The conductive pillars 600 may be formed through a plating process. The conductive pillars 600 may be formed by plating and growing a conductive material from the portions 400E of the plating seed layer 400 exposed in the openings 500H. The plating seed layer 400 is a layer that is utilized to forms the conductive pillars 600 and is formed under the resist layer 500. Each of the conductive pillars 600 is formed as a layer containing a metallic material such as copper (Cu). The plating process is performed such that a height or thickness of the conductive pillar 600 is substantially the same as the height of the first stack 100S-1 and the second stack 100S-2. Accordingly, the conductive pillars 600 do not completely fill the openings 500H as shown in FIG. 14. Because portions of the resist layer 500 are positioned between the conductive pillars 600, the conductive pillars 600 are electrically isolated from each other. The conductive pillars 600 are formed to laterally overlap the connecting patterns 210 of the semiconductor chips 100C.

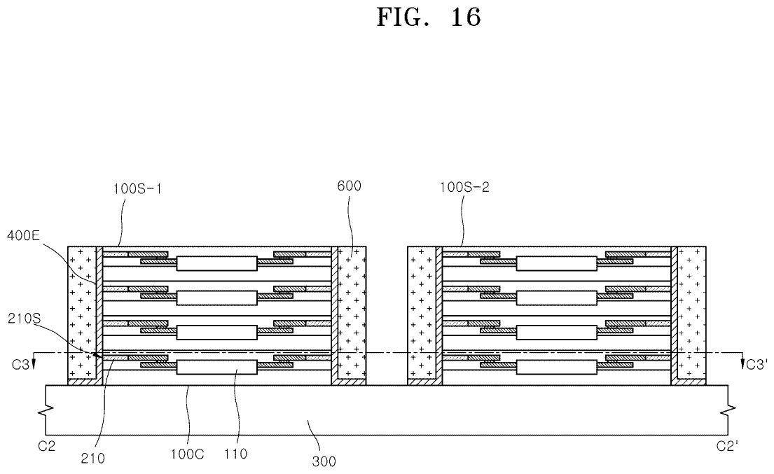

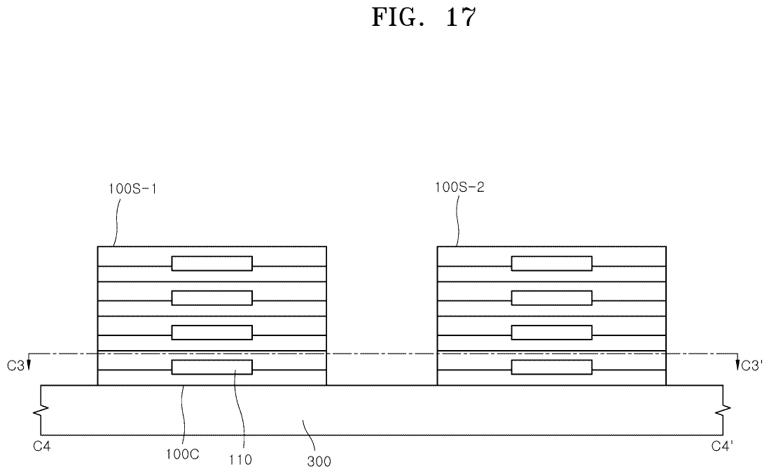

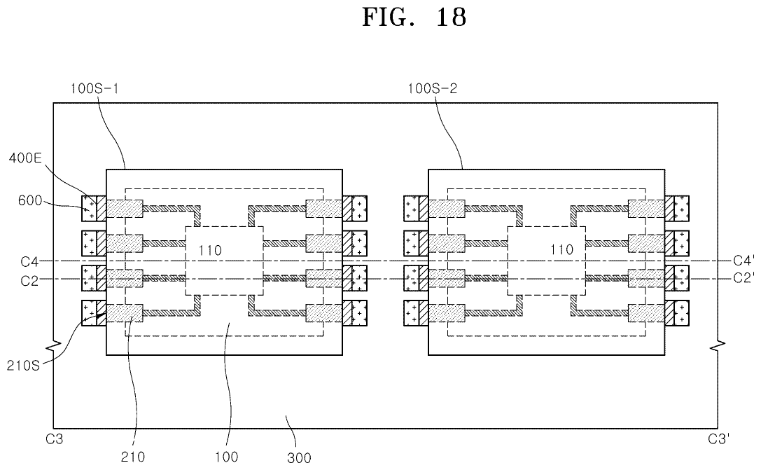

FIG. 16 to FIG. 18 are schematic views illustrating a separated plating seed layer 400 in accordance with the method of manufacturing the chip stack package according to an embodiment of the present disclosure. FIG. 16 illustrates a cross-section taken along the cutting line C2-C2′ of FIG. 18, FIG. 17 illustrates a cross-section taken along the cutting line C4-C4′ of FIG. 18, and FIG. 18 illustrates a cross-section taken along the cutting line C3-C3′ of FIG. 16 and FIG. 17.

Referring to FIG. 16 to FIG. 18, the resist layer (500 in FIG. 14) is removed. Portions of the plating seed layer 400, which are exposed as the resist layer 500 is removed, may be selectively removed. The portions of the plating seed layer 400 exposed to the outer surface of the conductive pillars 600 may be optionally removed and portions 400E of the plating seed layer 400 adjacent to the conductive pillars 600 may optionally remain. The remaining portions 400E of the plating seed layer 400 are separated or spaced apart from each other. The remaining portions 400E of the plating seed layer 400 are exposed in the openings, such as 500H in FIG. 14.

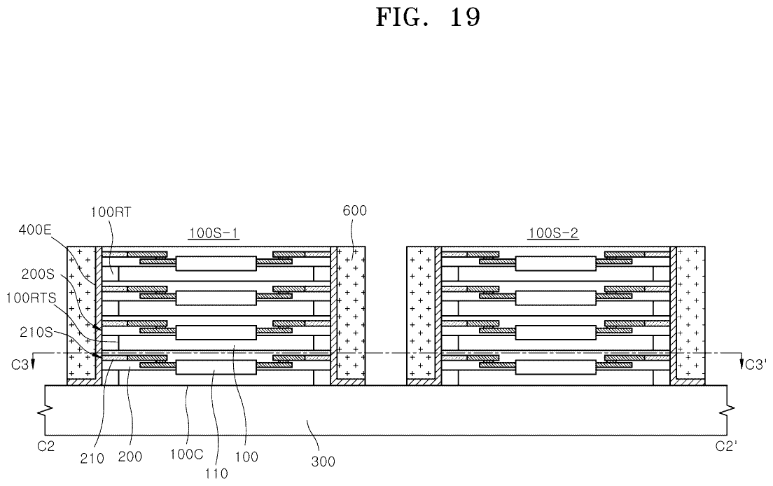

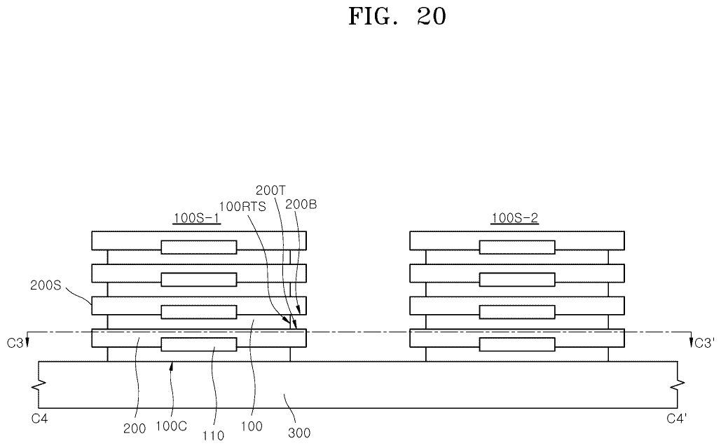

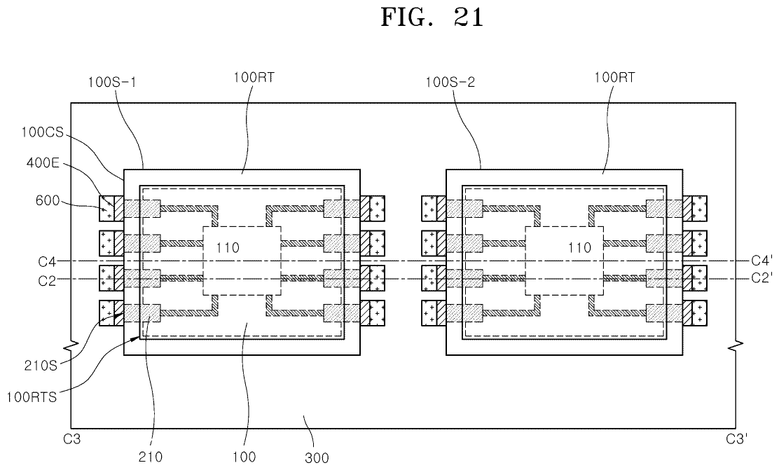

FIG. 19 to FIG. 21 are schematic views illustrating recessed semiconductor substrates 100 during the method of manufacturing the chip stack package according to an embodiment of the present disclosure. FIG. 19 illustrates a cross-section taken along the cutting line C2-C2′ of FIG. 21, FIG. 20 illustrates a cross-section taken along the cutting line C4-C4′ of FIG. 21, and FIG. 21 illustrates a cross-section taken along the cutting line C3-C3′ of FIG. 19 and FIG. 20.

Referring to FIG. 19 to FIG. 21, the semiconductor substrates 100 of the semiconductor chips 100C are recessed to separate the semiconductor substrates 100 from the conductive pillars 600. As the semiconductor substrates 100 are recessed, a trench 100RT is formed on the side surfaces of each of the first stack 100S-1 and the second stack 100S-2. As the trenches 100RT are formed, alternating inward and outward structures are formed on the side surfaces of the first stack 100S-1 and the second stack 100S-2, as illustrated in FIG. 20. As illustrated in FIG. 19, the conductive pillars 600 are spaced apart from the semiconductor substrates 100 by the width of the trench 100RT. The conductive pillars 600 are insulated from the semiconductor substrates 100. The portions 400E of the plating seed layer 400 adjacent to the conductive pillars 600 are spaced apart and insulated from the semiconductor substrates 100 by the trenches 100RT.

Each of the semiconductor substrates 100 of the semiconductor chips 100C is recessed and have a recessed side surface 100RTS that is laterally recessed to remove material from the diced side surfaces 100S. Each of the semiconductor substrates 100 is recessed and has the side surface 100RTS that is recessed from the side surface 200S of each of the first dielectric layers 200, as illustrated in FIG. 20. The recessed side surfaces 100RTS of the semiconductor substrates 100 are recessed from the first side surfaces 210S of the connecting patterns 210. Portions of the outer edges of the semiconductor substrates 100 are removed to recess the semiconductor substrates 100 such that the recessed edges of the semiconductor substrates 100, referred to as the recessed side surfaces 100RTS, are separated or distanced from the side surfaces 200S of the first dielectric layers 200. The semiconductor substrates 100 are recessed such that portions of the surfaces 200B and 200T of the first dielectric layer 200 are exposed to the recessed trenches 100RT.

An etchant may be applied to the first stack 100S-1 and the second stack 100S-2 of the semiconductor chips 100C to selectively remove portions of the semiconductor substrates 100 exposed to the conductive pillars 600. Accordingly, as illustrated in FIG. 20, as the semiconductor substrates 100 are etched away from the diced side surfaces 100S and the side surfaces 200S of the first dielectric layers 200, and the trenches 100RT are formed. This recess process may be performed by dry etching or wet etching. When the recess process is performed by wet etching, the recess process may be performed by a dip-out method in which the first stack 100S-1 and the second stack 100S-2 of the semiconductor chips 100C are immersed in an etchant solution. The etchant solution may include nitric acid.

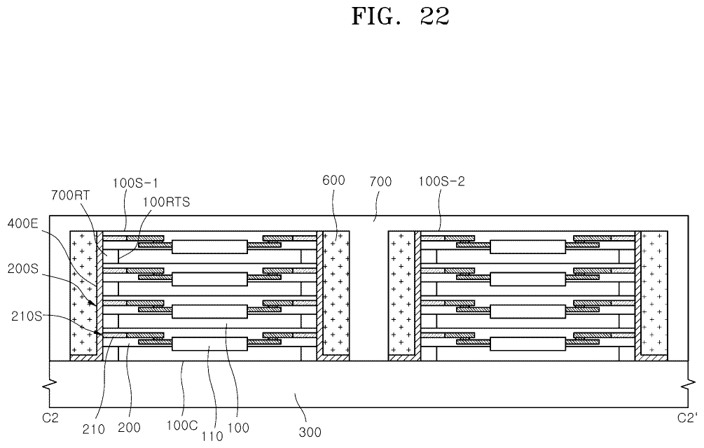

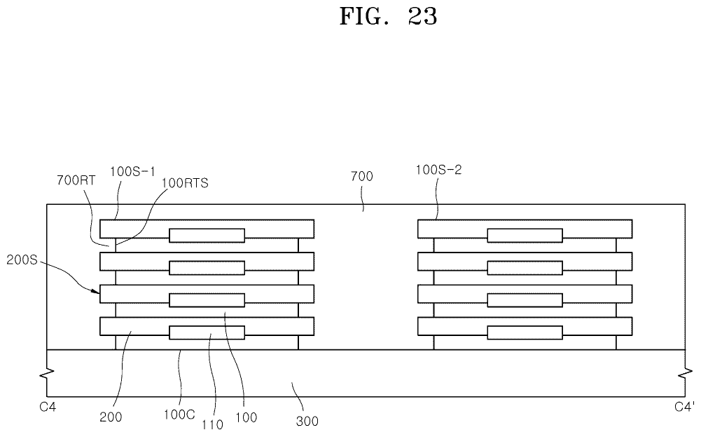

FIG. 22 and FIG. 23 are schematic views illustrating a second dielectric layer 700 formed during the method of manufacturing the chip stack package according to an embodiment of the present disclosure. FIG. 22 illustrates a cross-section taken along the cutting line C2-C2′ of FIG. 21, and FIG. 23 illustrates a cross-section taken along the cutting line C4-C4′ of FIG. 21.

Referring to FIG. 22 and FIG. 23, the second dielectric layer 700 is formed covering the first stack 100S-1 and the second stack 100S-2 as well as the base 300. The second dielectric layer 700 is formed to cover the conductive pillars 600 and to fill the spaces between the recessed semiconductor substrates 100 and the conductive pillars 600. The second dielectric layer 700 fills the space between the first stack 100S-1 and the second stack 100S-2 and fills the recessed trenches 100RT. The conductive pillars 600 extend substantially vertically across the semiconductor chips 100C, along the side surfaces 100CS of the stacked semiconductor chips 100C. The portions 700RT of the second dielectric layer 700, which fill the recessed trenches 100RT, insulate the conductive pillars 600 from the semiconductor substrates 100. The second dielectric layer 700 advantageously fills the spaces between the conductive pillars 600. The conductive pillars 600 are electrically insulated from each other by the second dielectric layer 700.

The second dielectric layer 700 may include a photosensitive dielectric layer. The second dielectric layer 700 may include a photosensitive polymer layer. The photosensitive polymer layer may include a photosensitive polymer material such as polyimide isoindro quindzoline (PIQ).

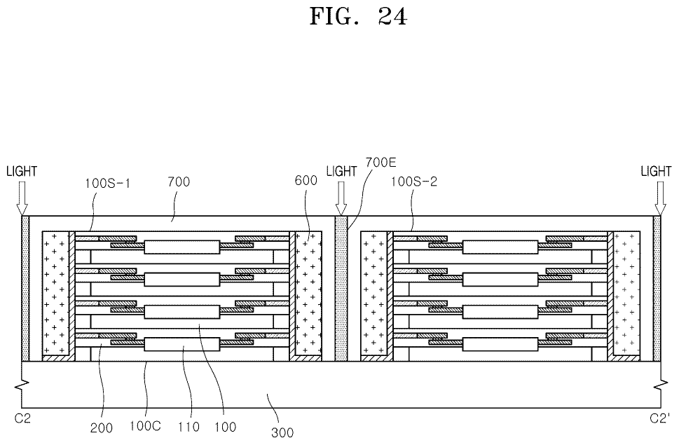

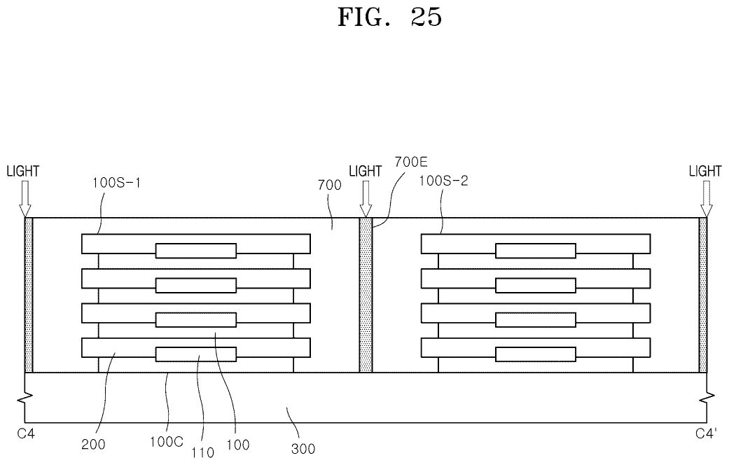

FIG. 24 and FIG. 25 are schematic views illustrating exposed portions 700E of the second dielectric layer 700 during the method of manufacturing the chip stack package according to an embodiment of the present disclosure. FIG. 24 illustrates a cross-section taken along the cutting line C2-C2′ of FIG. 21, and FIG. 25 illustrates a cross-section taken along the cutting line C4-C4′ of FIG. 21, except that FIG. 24 and FIG. 25 include the second dielectric layer 700 not included in FIG. 21.

Referring to FIG. 24 and FIG. 25, the portions 700E of the second dielectric layer 700 are selectively exposed. Using the photolithography process, light for exposure is irradiated on the portions 700E of the second dielectric layer 700. The portions 700E of the second dielectric layer 700 are exposed by irradiation of light. The portions 700E of the second dielectric layer 700 are located between the first stack 100S-1 and the second stack 100S-2. The portions 700E of the second dielectric layer 700 are positioned between conductive pillars 600 attached to the first stack 100S-1 and conductive pillars 600 attached to the second stack 100S-2.

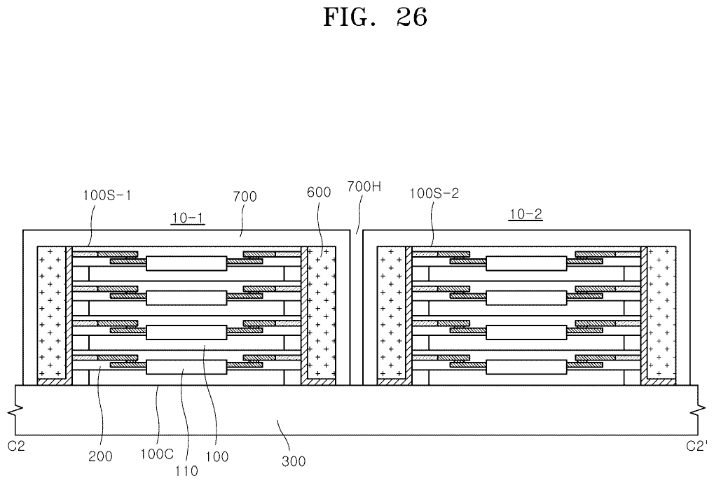

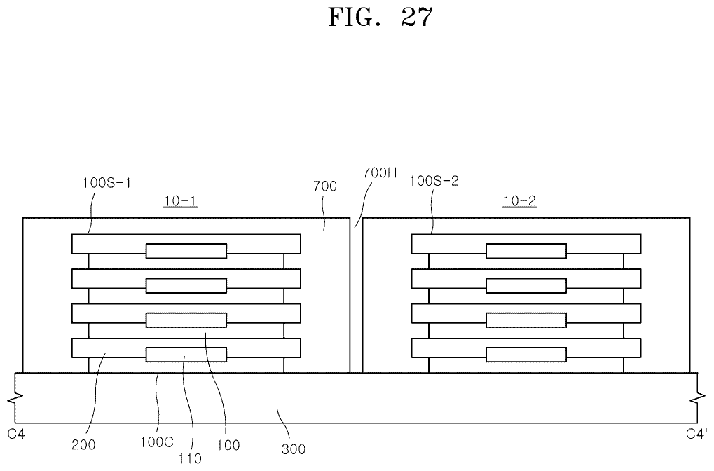

FIG. 26 and FIG. 27 are schematic views illustrating the second dielectric layer 700 after removing the portions 700E of the second dielectric layer 700 during the method of manufacturing the chip stack package according to an embodiment of the present disclosure. FIG. 26 illustrates a cross-section taken along the cutting line C2-C2′ of FIG. 21, and FIG. 27 illustrates a cross-section taken along the cutting line C4-C4′ of FIG. 21, except that FIG. 24 and FIG. 25 include the second dielectric layer 700 not included in FIG. 21.

Referring to FIG. 26 and FIG. 27, the exposed portions 700E of the second dielectric layer 700 shown in FIG. 24 and FIG. 25 are selectively removed, leaving behind holes 700H that separate the first stack 100S-1 and the second stack 100S-2. The exposed portions 700E of the second dielectric layer 700 are removed with a developer. A first chip stack package 10-1 and a second chip stack package 10-2 are produced or formed including the first stack 100S-1 and the second stack 100S-2, respectively. During the process of separating the first stack 100S-1 from the second stack 100S-2 and producing the first chip stack package 10-1 and the second chip stack package 10-2, dicing devices such as a sawing blade or laser need not be utilized. The first chip stack package 10-1 and the second chip stack package 10-2 are separated from the base 300.

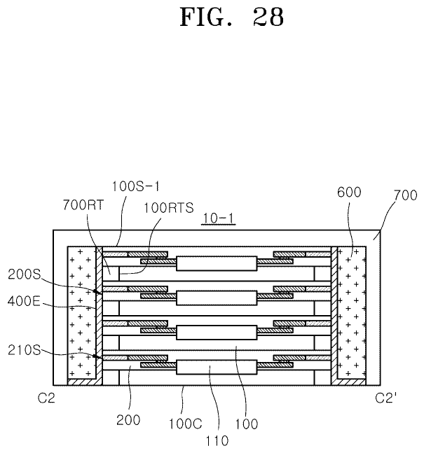

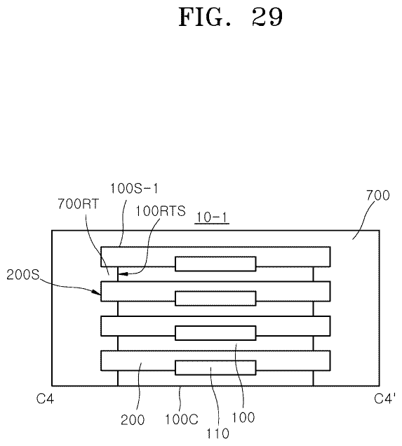

FIG. 28 and FIG. 29 are schematic views illustrating the first chip stack package 10-1 according to an embodiment of the present disclosure. FIG. 28 illustrates a cross-section taken along the cutting line C2-C2′ of FIG. 21, and FIG. 29 illustrates a cross-section taken along the cutting line C4-C4′ of FIG. 21, except that FIG. 24 and FIG. 25 include the second dielectric layer 700 not included in FIG. 21.

Referring to FIG. 28 and FIG. 29, the first chip stack package 10-1 includes the first stack 100S-1 in which the semiconductor chips 100C are stacked, the conductive pillars 600, and the second dielectric layer 700. Each of the semiconductor chips 100C includes the semiconductor substrate 100, the first dielectric layer 200 positioned on the semiconductor substrate 100, and the connecting patterns 210 positioned within the first dielectric layer 200 and having the side surfaces 210S adjacent to the side surface 200S of the first dielectric layer 200. One or more conductive pillars 600 are connected to the side surfaces 210S of the connecting patterns 210 of the stacked semiconductor chips 100C thereby connecting the stacked semiconductor chips 100C to each other. Each of the semiconductor substrates 100 is recessed inwardly away or distanced from the second side surface 200S of the first dielectric layer 200. The semiconductor substrates 100 have the recessed side surfaces 100RTS spaced apart from the side surfaces 200S of the first dielectric layers 200. The recessed trenches 100RT adjacent to the recessed side surfaces 100RTS are formed on the side surface of the first stack 100S-1. The conductive pillars 600 are spaced apart from the semiconductor substrates 100 by the recessed trenches 100RT. The second dielectric layer 700 covers the conductive pillars 600 and portions 700RT of the second dielectric layer 700 extend to fill the recessed trenches 100RT. The portions 700RT of the second dielectric layer 700, which fill the recessed trenches 100RT, electrically isolate the conductive pillars 600 from the semiconductor substrates 100. The conductive pillars 600 provide advantages over other vertical interconnection methods including through-silicon vias (TSVs) and wire bonding to connect the semiconductor chips stacked substantially vertically to each other in a chip stack package.

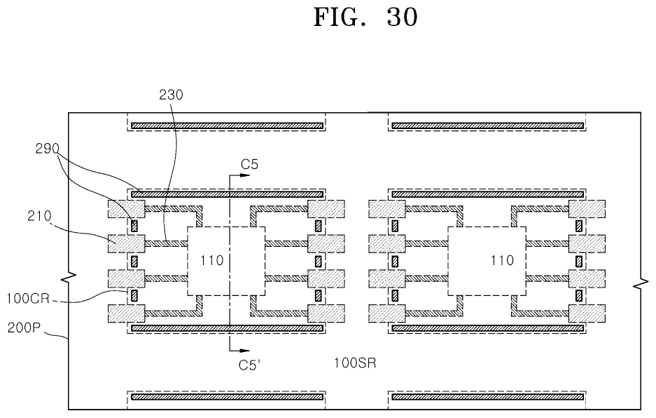

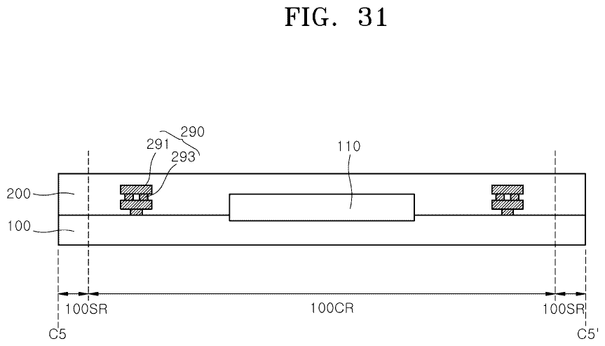

FIG. 30 and FIG. 31 are schematic views illustrating guard ring structures 290 formed during the method of manufacturing the chip stack package according to an embodiment of the present disclosure. FIG. 31 illustrates a cross-section taken along the cutting line C5-C5′ of FIG. 30.

Referring to FIG. 30, during the process of forming the semiconductor chips 100C in FIG. 4, a plurality of guard ring structures 290 may be formed over the parent substrate 100P. The guard ring structures 290 are elements that protect the integrated circuits 110 disposed in the chip regions 100CR from the external environmental factors. Some of the guard ring structures 290 extend along the edges of the chip regions 100CR. Other guard ring structures 290 are positioned spaced apart from the connecting patterns 210 and between the connecting patterns 210. The connecting patterns 210 are located between the guard ring structures 290 and in the scribe lane regions 100SR.

Referring to FIG. 31, the guard ring structures 290 may be positioned within the first dielectric layer 200 or within the parent dielectric layer 200P. The first dielectric layer 200 or the parent dielectric layer 200P may cover the guard ring structures 290 to insulate the guard ring structures 290. Each of the guard ring structures 290 may be formed in a structure in which a plurality of guard ring conductive layers 291 and a plurality of guard ring conductive vias 293 are stacked.

By forming the guard ring structures 290 over the parent substrate 100P or the semiconductor substrates 100, the guard ring structures 290 may be maintained in the first dielectric layer 200 in the semiconductor chips 100C illustrated in FIG. 3 and FIG. 4. The guard ring structures 290 may be included in the diced semiconductor chips 100C.

Although the detailed embodiments of the present disclosure are described in the present disclosure, those skilled in the art will understand that various modifications, additions, and substitutions are possible, without departing from the scope, concepts, and spirit of the present disclosure. Accordingly, the embodiments disclosed in the present specification should be considered not from a restrictive standpoint but from an illustrative standpoint. Therefore, the scope of the present disclosure should not be limited to the foregoing embodiments. All changes within the meaning and range of equivalency of the claims are included within their scope.

What is claimed is:

1. A method of manufacturing a chip stack package, the method comprising:
stacking semiconductor chips, each of the semiconductor chips including a semiconductor substrate, a first dielectric layer positioned over the semiconductor substrate, and a connecting pattern positioned within the first dielectric layer, wherein the connecting pattern has a first side surface, the first dielectric layer has a second side surface, and the second side surface and the first side surface are exposed;
forming conductive pillars connected to a plurality of the first side surfaces of the connecting patterns of the stacked semiconductor chips, connecting the stacked semiconductor chips to each other;
recessing the semiconductor substrates from the second side surfaces; and
forming a second dielectric layer covering the conductive pillars and filling spaces between the recessed semiconductor substrates and the conductive pillars.

2. The method of claim 1,
wherein each of the first dielectric layers includes:
a first surface facing the semiconductor substrate;
a second surface opposite to the first surface; and
wherein the second side surface is between the first surface and the second surface, and
wherein recessing the semiconductor substrates includes:
removing a portion of edges of the semiconductor substrates to recess the semiconductor substrates, wherein recessed edges of the semiconductor substrates are distanced from the second side surfaces, and
exposing a portion of the first surfaces of the first dielectric layers and a portion of the second surfaces of the first dielectric layers.

3. The method of claim 1, wherein the first dielectric layer includes silicon oxide, and the semiconductor substrate includes a silicon layer.

4. The method of claim 1, wherein each conductive pillar extends across an outer side surface of one of the stacked semiconductor chips.

5. The method of claim 1, wherein the conductive pillars are electrically insulated from each other by the second dielectric layer.

6. The method of claim 1, wherein each of the conductive pillars includes a metallic material.

7. The method of claim 1, wherein forming the conductive pillars includes:
forming a resist layer covering the stacked semiconductor chips;
forming openings in the resist layer and exposing the first side surfaces of the connecting patterns;
filling the openings with a conductive material to form the conductive pillars; and
removing the resist layer.

8. The method of claim 1, further comprising forming a plating seed layer over at least part of the stacked semiconductor chips.

9. The method of claim 8, further comprising:
forming a resist layer covering the stacked semiconductor chips;
forming openings in the resist layer; and
plating the conductive material from a first portion of the plating seed layer exposed in the openings.

10. The method of claim 9, further comprising removing a second portion of the plating seed layer exposed to the outer surface of the conductive pillars while removing the resist layer.

11. The method of claim 1, further comprising removing a portion of the second dielectric layer by exposing and developing the portion of the second dielectric layer.

12. The method of claim 11, wherein the second dielectric layer includes a photosensitive polymer layer.

13. The method of claim 12, wherein the photosensitive polymer layer includes polyimide isoindro quindzoline (PIQ).

14. The method of claim 1, wherein stacking the semiconductor chips comprises directly bonding a surface of the first dielectric layer of a first semiconductor chip to a surface of the semiconductor substrate of a second semiconductor chip without an adhesive material.

15. The method of claim 1, further comprising forming the semiconductor chips before stacking the semiconductor chips, wherein forming the semiconductor chips includes:
forming a parent dielectric layer comprising the first dielectric layer and positioning the connecting patterns within the parent dielectric layer that is disposed over a parent substrate comprising the semiconductor substrates; and
dicing the parent substrate and the parent dielectric layer to expose the first side surfaces of the connecting patterns.

16. The method of claim 15, wherein the parent substrate includes chip regions and a scribe lane region between consecutive chip regions, further comprising forming each connecting pattern to extends across a chip region and the scribe lane region.

17. The method of claim 16, further comprising:
forming integrated circuits in the chip regions of the parent substrate, and
connecting the connecting patterns to the integrated circuits.

18. The method of claim 16, further comprising forming a plurality of guard ring structures over the parent substrate and extending along edges of the chip regions within the chip regions of the parent substrate, wherein the plurality of guard ring structures are positioned between the connecting patterns and spaced apart from the connecting patterns.

19. The method of claim 1, wherein a semiconductor chip of the semiconductor chips further includes a plurality of guard ring structures within the first dielectric layer, between the connecting patterns, and spaced apart from the connecting patterns.

20. A method of manufacturing a chip stack package, the method comprising:
forming semiconductor chips, each of the semiconductor chips including a semiconductor substrate, a first dielectric layer positioned over the semiconductor substrate, and a connecting pattern within the first dielectric layer, wherein the connecting pattern has a first side surface, the first dielectric layer has a second side surface, and the second side surface and the first side surface are exposed;
arranging a first stack of semiconductor chips spaced apart from a second stack of semiconductor chips over a base;
forming conductive pillars connecting a plurality of the first side surfaces of the connecting patterns of the stacked semiconductor chips, wherein a first section of the conductive pillars is connected to the first stack and a second section of the conductive pillars is connected to the second stack;
recessing edges of the semiconductor substrates included in the first stack and the second stack from the second side surfaces;
forming a second dielectric layer covering the first stack and the second stack; and
removing portions of the second dielectric layer by exposing and developing the portions to separate the first stack from the second stack.

21. The method of claim 20, wherein the second dielectric layer includes a photosensitive polymer layer.

22. The method of claim 20, further comprising forming the second dielectric layer to cover the conductive pillars and fill spaces between the recessed semiconductor substrates and the conductive pillars.

23. A chip stack package comprising:
a stack comprising stacked semiconductor chips, each of the semiconductor chips including a semiconductor substrate, a first dielectric layer positioned over the semiconductor substrate, and a connecting pattern within the first dielectric layer, wherein the connecting pattern has a first side surface, the first dielectric layer has a second side surface, and the second side surface is adjacent to the first side surface;
conductive pillars connected to a plurality of the first side surfaces of the connecting patterns of the stacked semiconductor chips, connecting the stacked semiconductor chips to each other; and
a second dielectric layer covering the conductive pillars,
wherein the semiconductor substrates are recessed from the second side surfaces, and
wherein the second dielectric layer fills spaces between the recessed semiconductor substrates and the conductive pillars.

24. The chip stack package of claim 23, wherein each conductive pillar extends across an outer side surface of one of the stacked semiconductor chips.

25. The chip stack package of claim 23, wherein the stacked semiconductor chips are formed by directly bonding a surface of the first dielectric layer of a first semiconductor chip to a surface of the semiconductor substrate of a second semiconductor chip without an adhesive material.

26. The chip stack package of claim 23, wherein a semiconductor chip of the semiconductor chips further includes a plurality of guard ring structures within the first dielectric layer, spaced apart from the connecting patterns, and located between the connecting patterns.
